(19) United States
(12) Patent Application Publication
(10) Pub. No.: US 2008/0248598 A1
(43) Pub. Date: Oct. 9, 2008

(54) METHOD AND APPARATUS FOR DETERMINING CHARACTERISTICS OF A STRESSED MATERIAL USING SCATTEROMETRY

(76) Inventors: Rohit Pal, Fishkill, NY (US); Alok Vaid, Wappingers Falls, NY (US)

Correspondence Address: WILLIAMS, MORGAN & AMERSON, 10333 RICHMOND, SUITE 1100, HOUSTON, TX, 77042, US

(21) Appl. No.: 11/697,955

(22) Filed: Apr. 9, 2007

(51) Int. Cl. H01L 21/66; H01L 21/306; H01L 23/58

(52) U.S. Cl. 438/8; 156/345.25; 257/48; 438/16; 257/E21.53; 257/E23.001; 257/E21.215

(57) ABSTRACT

A method includes illuminating at least a portion of a first grid including a first plurality of stressed material regions formed at least partially in a semiconducting material. Light reflected from the illuminated portion of the first grid is measured to generate a first reflection profile. A characteristic of the first plurality of stressed material regions is determined based on the first reflection profile. A test structure includes a first plurality of stressed material regions recessed with respect to a surface of a semiconductor layer and defining a first grid. A first plurality of exposed portions of the semiconductor layer is disposed between each of the first plurality of stressed material regions.

### CROSS-REFERENCE TO RELATED APPLICATIONS

Not applicable.

### BACKGROUND OF THE INVENTION

The present invention relates generally to semiconductor device manufacturing and, more particularly, to a method and apparatus for determining characteristics of a stressed material using scatterometry.

The fabrication of complex integrated circuits involves the fabrication of a large number of transistor elements, which are used in logic circuits as switching devices. Generally, a plurality of process technologies are currently practiced for complex circuitry, such as microprocessors, storage chips, and the like. One process technology currently used is complimentary metal oxide silicon (CMOS) technology, which provides benefits in terms of operating speed, power consumption, and/or cost efficiency. In CMOS circuits, complementary transistors (e.g., p-channel transistors and n-channel transistors) are used for forming circuit elements, such as inverters and other logic gates to design complex circuit assemblies, such as CPUs, storage chips, and the like.

During the fabrication of complex integrated circuits using CMOS technology, millions of transistors are formed on a substrate including a crystalline semiconductor layer. A transistor includes pn-junctions that are formed by an interface of highly doped drain and source regions with an inversely doped channel region disposed between the drain region and the source regions. The conductivity of the channel region, i.e., the drive current capability of the conductive channel, is controlled by a gate electrode formed in the vicinity of the channel region and separated therefrom by a thin insulating layer. A conductive channel is formed when an appropriate control voltage is applied to the gate electrode. The conductivity of the channel region depends on the dopant concentration, the mobility of the majority charge carriers, and—for a given extension of the channel region in the transistor width direction—on the distance between the source and drain regions, which is also referred to as channel length.

Hence, the overall conductivity of the channel region substantially determines an aspect of the performance of the MOS transistors. By reducing the channel length, and accordingly, the channel resistivity, an increase in the operating speed of the integrated circuits may be achieved.

The continuing shrinkage of the transistor dimensions does raise issues that might offset some of the advantages gained by the reduced channel length. For example, highly sophisticated vertical and lateral dopant profiles may be required in the drain and source regions to provide low sheet and contact resistivity in combination with a desired channel controllability. Moreover, the gate dielectric material may also be adapted to the reduced channel length in order to maintain the required channel controllability. However, some mechanisms for obtaining a high channel controllability may also have a negative influence on the charge carrier mobility in the channel region of the transistor, thereby partially offsetting the advantages gained by the reduction of the channel length.

The continuous size reduction of the critical dimensions, i.e., the gate length of the transistors, necessitates the adaptation of current process techniques and possibly the development of new process techniques. One technique for enhancing the channel conductivity of the transistor elements involves increasing the charge carrier mobility in the channel region for a given channel length, thereby offering the potential for achieving a performance improvement that is comparable with the advance to a future technology node while avoiding or at least postponing many of the process adaptations associated with device scaling.

One efficient mechanism for increasing the charge carrier mobility is to modify the lattice structure in the channel region, for instance by creating tensile or compressive stress in the vicinity of the channel region so as to produce a corresponding strain in the channel region, which results in a modified mobility for electrons and holes, respectively. For example, creating tensile strain in the channel region for a standard crystallographic configuration of the active silicon material increases the mobility of electrons, which, in turn, may directly translate into a corresponding increase in the conductivity. On the other hand, compressive strain in the channel region may increase the mobility of holes, thereby providing the potential for enhancing the performance of p-type transistors.

The introduction of stress or strain engineering into integrated circuit fabrication is a promising approach for future device generations. Strained silicon may be considered as a “new” type of semiconductor material that enables the fabrication of fast powerful semiconductor devices without requiring expensive semiconductor materials and also allows the use of many of the well-established current manufacturing techniques.

One technique for inducing stress in the channel region involves introducing, for instance, a silicon/germanium layer next to the channel region so as to induce a compressive stress that may result in a corresponding strain. The transistor performance of p-channel transistors may be considerably enhanced by the introduction of stress-creating layers next to the channel region. For this purpose a strained silicon/germanium layer may be formed in the drain and source regions of the transistors. The compressively strained drain and source regions create uni-axial strain in the adjacent silicon channel region. When forming the Si/Ge layer, the drain and source regions of the PMOS transistors are selectively recessed, while the NMOS transistors are masked. Subsequently, the silicon/germanium layer is selectively formed by epitaxial growth. For generating a tensile strain in the silicon channel region, Si/C may be used instead of SiGe.

FIG. 1A shows a cross-sectional view of a semiconductor device 100 in an early manufacturing stage. The semiconductor device 100 comprises a semiconductor layer 110 of a first semiconductor material in and/or on which circuit elements, such as transistors, capacitors, resistors, and the like may be formed. The semiconductor layer 110 may be provided on a substrate (not shown), e.g. on a bulk semiconductor substrate or a semiconductor-on-insulator (SOI) substrate, wherein the semiconductor layer 110 may be formed on a buried insulation layer. The semiconductor layer 110 may be a silicon-based crystalline semiconductor layer comprising silicon with a concentration of at least 50%. The semiconductor layer 110 may represent a doped silicon layer as is typically used for highly complex integrated circuits having transistor elements with a gate length around 50 nm or below.

A gate electrode 120 may be formed above the semiconductor layer 110. The gate electrode 120 may be formed of doped polysilicon or other suitable material which is provided above the semiconductor layer 110 and is separated therefrom by a gate insulation layer 130. The first semiconductor material 110 forms a channel region 140 for a finished transistor. Sidewalls of the gate electrode 120 are provided with disposable sidewall spacers 150. The disposable sidewall spacers 150 may consist of any appropriate dielectric material, such a silicon nitride, silicon dioxide, or mixtures thereof. The disposable sidewall spacers 150 may be used as an etch and growth mask in an etch process and an epitaxial growth process for the formation of an embedded strained semiconductor region.

The semiconductor device 100 of FIG. 1A further comprises a cavity or recess 160 defined in the semiconductor layer 110. The recess 160 may be formed by performing a well established anisotropic etch process while using the sidewall spacers 150 as a mask. Therefore, the disposable sidewall spacers 150 determine the lateral distance between the sidewalls 165 of the gate electrode 120 and the recess 160.

It should be appreciated that after the formation of the recess 160, the semiconductor device 100 may be subjected to any necessary or suitable pretreatments for preparing the device 100 for a subsequent epitaxial growth process. Thereafter, a stressed semiconductor material 170 (see FIG. 1B) is grown in the cavity 160. The stressed semiconductor material 170 comprises a first alloy component and a second alloy component. In an illustrative embodiment, the first alloy component is silicon and the second alloy component is germanium. The growth of the stressed semiconductor material 170 in the cavity 160 may performed by using a selective epitaxial growth process using the material of the cavity bottom and/or sidewalls as a template. In one illustrative embodiment, an appropriate deposition atmosphere may be established comprising of a silicon-containing precursor material and a germanium-containing precursor material. Typically in selective epitaxial growth processes, the process parameters, such as pressure, temperature, type of carrier gases and the like are selected such that substantially no material is deposited on dielectric surfaces such as the surfaces of the spacer 150 and a possible capping layer (not shown), while a deposition is obtained on exposed surfaces of the first semiconductor layer 110, thereby using this layer as a crystalline template, which substantially determines the crystalline structure of the epitaxially grown stressed semiconductor material 170. Since the covalent radius of germanium is larger than the covalent radius of the silicon, growing the silicon/germanium material on a silicon template results in a strained silicon/germanium layer which induces a compressive strain in the channel region 140. It should be appreciated that any appropriate stressed semiconductor material may be used, depending on the type of the first semiconductor material and the desired strain type in the first semiconductor material. For example in other embodiments, which use silicon or a silicon-based material as the first semiconductor material, the stressed semiconductor material may be silicon/carbon (SiC) for inducing a tensile strain in the channel region 140.

During the formation of stressed silicon structures, several parameters affect the net stress, which in turn modulates the hole or electron mobility. These parameters include the proximity of the strained material cavity to the gate electrode, the cavity depth, the stress dopant (e.g., germanium or carbon) content of the stressed film, implant conditions, etc. The control of each of these parameters may be attempted to enhance strain and thereby enhance the performance of the completed devices.

The behavior of a stressed silicon structure is strongly dependent on geometric confinement. Hence, optimization based on blanket wafer studies and metrology measurements on large pad areas is ineffective for attempting to collect data for controlling the fabrication of devices with much smaller stressed layer cavities. Spatial variations in growth rates, etch rates, etc. on a wafer (i.e., within die and/or across wafer) caused by the local pattern density differences, non-uniformity in process conditions, etc. result in variations in the final device structure. These variations are commonly referred to as loading effects. Current techniques for monitoring actual devices involves costly and time consuming cross-sectional analysis, which hinders the ability to characterize and optimize the devices for increased performance.

This section of this document is intended to introduce various aspects of art that may be related to various aspects of the present invention described and/or claimed below. This section provides background information to facilitate a better understanding of the various aspects of the present invention. It should be understood that the statements in this section of this document are to be read in this light, and not as admissions of prior art. The present invention is directed to overcoming, or at least reducing the effects of, one or more of the problems set forth above.

### BRIEF SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

One aspect of the present invention is seen in a method that includes illuminating at least a portion of a first grid including a first plurality of stressed material regions formed at least partially in a semiconducting material. Light reflected from the illuminated portion of the first grid is measured to generate a first reflection profile. A characteristic of the first plurality of stressed material regions is determined based on the first reflection profile.

Another aspect of the present invention is seen in a test structure including a first plurality of stressed material regions recessed with respect to a surface of a semiconductor layer and defining a first grid. Members of a first plurality of exposed portions of the semiconductor layer are disposed between members of the first plurality of stressed material regions.

### BRIEF DESCRIPTION OF THE SEVERAL VIEWS OF THE DRAWINGS

The invention will hereafter be described with reference to the accompanying drawings, wherein like reference numerals denote like elements, and:

FIGS. 1A and 1B are cross-section diagrams of exemplary prior art devices including recessed stressed layers to induce stress in the channel region;

FIG. 2 is a simplified diagram of an illustrative processing line for processing wafers in accordance with one illustrative embodiment of the present invention;

FIGS. 3A and 3B are cross-section views of exemplary test structures that may be used to generate metrology data in the processing line of FIG. 1;

FIG. 4 is a simplified view of the scatterometry tool of FIG. 2;

FIGS. 5A, 5B, and 5C illustrate a library of exemplary scatterometry curves used to characterize the wafer measured in the scatterometry tool of FIG. 4; and

FIG. 6 is a simplified flow diagram of a method for determining grid dimensions using scatterometry measurements in accordance with another illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

One or more specific embodiments of the present invention will be described below. It is specifically intended that the present invention not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the present invention unless explicitly indicated as being “critical” or “essential.”

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

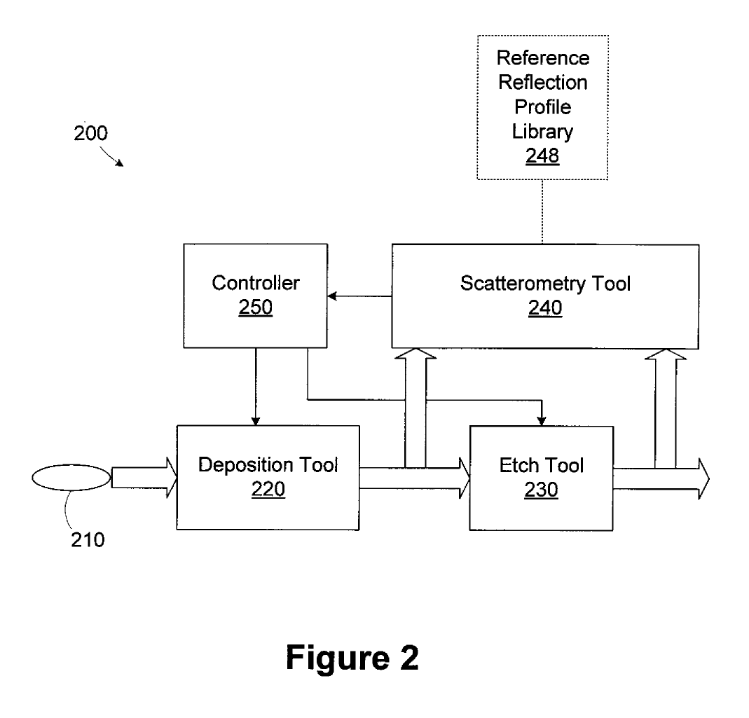

Referring now to the drawings wherein like reference numbers correspond to similar components throughout the several views and, specifically, referring to FIG. 2, the present invention shall be described in the context of an illustrative processing line 200 for processing wafers 210 in accordance with one illustrative embodiment of the present invention is provided. In the illustrated embodiment, the processing line 200 includes a deposition tool 220 for forming one or more process layers on the wafer 210, an etch tool 230 for etching various features in the various process layers, a scatterometry tool 240, and a controller 250.

The deposition tool 220 may be used to form the process layers for the gate electrode 120, the gate insulation layer 130, the sidewall spacers 150, and/or the stressed semiconductor material 170. The etch tool 230 may be employed to form the gate electrode 120, the sidewall spacers 150, and or the recesses 160. For ease of illustration and to avoid obscuring the present invention, only a portion of the processing line 200 is illustrated. An actual implementation of the processing line 200 may have additional types of tools and multiples instances of each tool type. For example, different etch tools and/or deposition tools may be used to form the process layers or features described above.

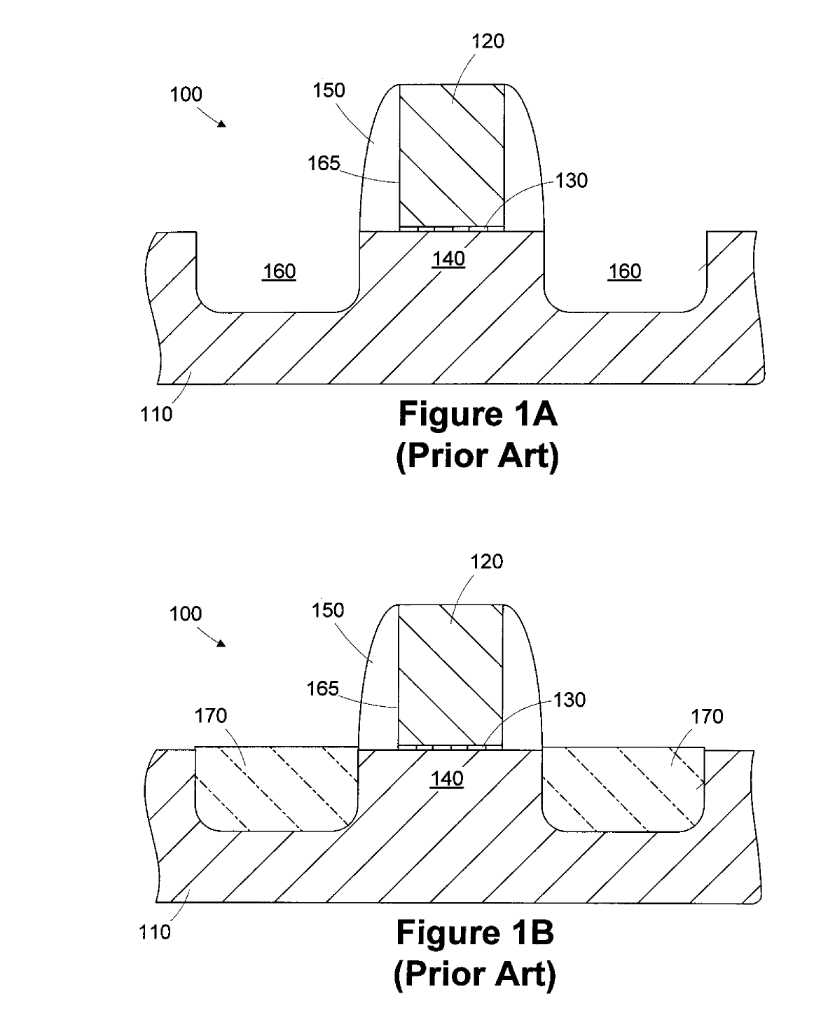

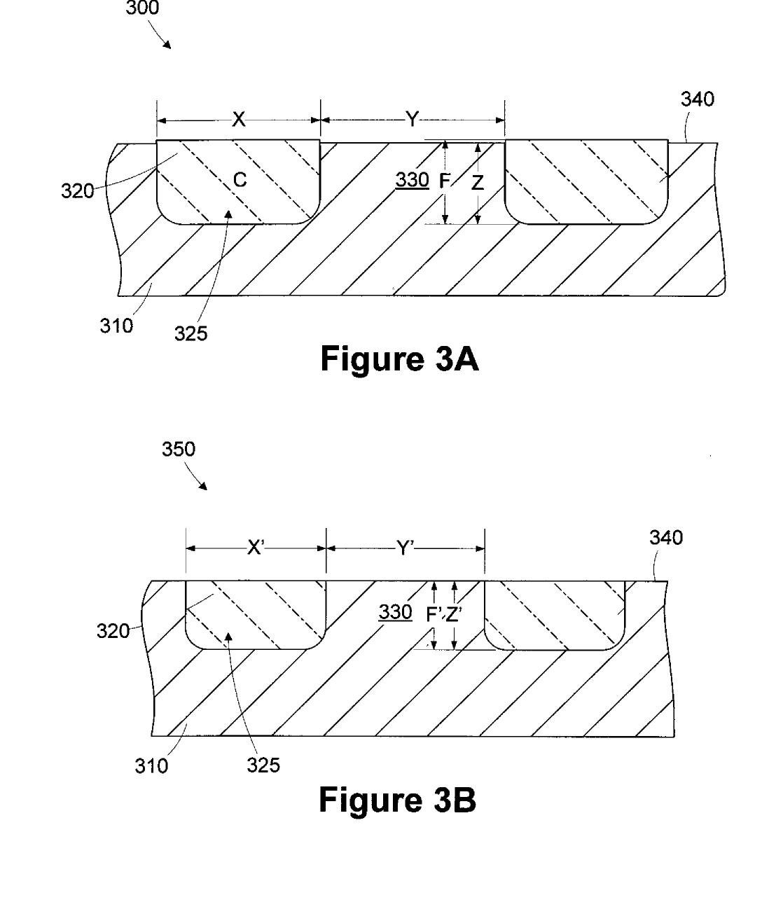

In general, the scatterometry tool 240 determines the characteristics of the recessed stressed layer of the exemplary semiconductor device 100 of FIG. 1B by measuring characteristics of a stressed layer test structure having features that are at least similar to the actual semiconductor device 100, as described in greater detail below with reference to FIGS. 3A and 3B. The scatterometry tool 240 includes optical hardware, such as an ellipsometer or reflectometer, and a data processing unit loaded with a scatterometry software application for processing data collected by the optical hardware. For example, the optical hardware may include a model OP5140 or OP5240 with a spectroscopic ellipsometer offered by Therma-Wave, Inc. of Freemont Calif. The data processing unit may comprise a profile application server manufactured by Timbre Technologies, a subsidiary of Tokyo Electron Limited, Inc. of Tokyo, Japan and distributed by Therma-Wave, Inc. The scatterometry tool 240 may be external or, alternatively, the scatterometry tool 240 may be installed in an in-situ arrangement.

The controller 250 provides feedback to the deposition tool 220 and/or the etch tool 230 based on the measurements generated by the scatterometry tool 240. The controller 250 adjusts the operating recipe of the controlled tool 220, 230 to improve the deposition and/or etching processes for subsequently processed wafers 210 to improve the recessed stressed layer characteristics.

In the illustrated embodiment, the controller 250 is a computer programmed with software to implement the functions described. However, as will be appreciated by those of ordinary skill in the art, a hardware controller designed to implement the particular functions may also be used. Moreover, the functions performed by the controller 250, as described herein, may be performed by multiple controller devices distributed throughout a system. Additionally, the controller 250 may be a stand-alone controller, it may be integrated into a tool, such as the deposition tool 220, etch tool 230, or the scatterometry tool 240, or it may be part of a system controlling operations in an integrated circuit manufacturing facility.

Portions of the invention and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Referring now to FIGS. 3A and 3B cross-section views of exemplary test structures 300, 350 for use by the scatterometry tool 240 for determining characteristics of the recessed stress regions are provided. The test structures 300, 350 are formed in a semiconductor layer 310. Recessed stressed material regions 320 are formed in the semiconductor layer 310 using a process similar to that used to form the stressed semiconductor material 170 of FIG. 1B for the actual semiconductor device 100. For example, recesses 325 maybe formed using a mask (e.g., photoresist) that corresponds dimensionally to the combination of the gate electrode 120 and the sidewall spacers 150 of the semiconductor device 100. Alternatively, dummy gate electrodes and spacers (not shown) may be formed using similar processes used to form the actual semiconductor devices 100. The stressed material regions 320 may be epitaxially grown in the recesses and the mask or dummy features may be subsequently removed. The characteristics of the test structure 300 vary. For example, the dimension X represents the width of the stressed material regions 320, the dimension Y represents the width of a simulated channel region 330, the dimension Z represents a depth of the stressed material regions 320 relative to a surface 340 of the semiconductor layer 310, the dimension F represents the fill height of the stressed material regions 320 (i.e., which may be above or below the surface 340 of the semiconductor layer 310, and the parameter C represents the stress dopant concentration of the stressed material regions 320 (i.e., the concentration of germanium or carbon dopant ions).

The test structure of FIG. 3B is similar to the structure of FIG. 3A, with the exception of the dimensions of the features. One or more of the dimensions X′, Y′, Z′ may be intentionally varied to represent different geometries expected in the actual devices fabricated on the wafer 210. Other parameters, such as the fill height, F′, may vary due to variations in the process. For example, the epitaxial growth process may exhibit pitch related variation resulting in differing fill heights for test structures 300, 350 with differing geometries.

By varying the dimensions of the test structures 300, 350, different devices sizes and/or pitches may be provided. These variations simulate different loading effects expected on the actual fabricated devices. Hence, an assortment of test structures 300, 350 may be provided to match the devices expected on the wafer 210. For example, test structures having the same Z dimensions, but different X and Y (i.e., pitch) dimensions may be provided. The test structures 300, 350 exhibit simplified topologies as compared to the topology of the actual semiconductor devices 100 (i.e., due to the absence of the gate electrode 120) to allow them to be more readily analyzed by the scatterometry tool 240.

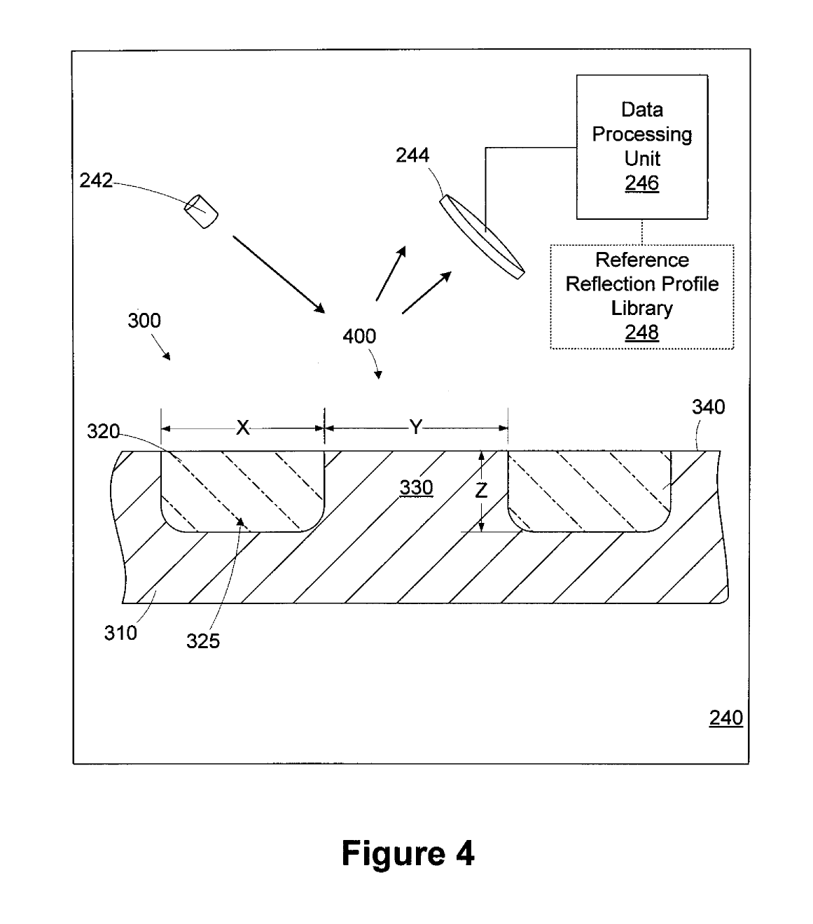

Turning now to FIG. 4, a simplified view of the scatterometry tool 240 loaded with a wafer 210 having the test structure 300 of FIG. 3A is provided. The scatterometry tool 240, includes a light source 242 and a detector 244 positioned proximate the test structure 300. The light source 242 of the scatterometry tool 240 illuminates at least a portion of a grid 400 defined by the plurality of stressed material regions 320, and the detector 244 takes optical measurements, such as intensity or phase, of the reflected light. A data processing unit 246 receives the optical measurements from the detector 244 and processes the data to identify characteristics of the grid 400. The grid 400 may include any number of the stressed material regions 320, depending on the particular embodiment.

The scatterometry tool 240 may use monochromatic light, white light, or some other wavelength or combinations of wavelengths, depending on the specific implementation. The angle of incidence of the light may also vary, depending on the specific implementation. The light analyzed by the scatterometry tool 240 typically includes a reflected component (i.e., incident angle equals reflected angle) and a refracted component (i.e., incident angle does not equal the reflected angle). For purposes of discussion here, the term “reflected” light is meant to encompass both components.

Variations, such as width, depth, spacing, fill height, and stress dopant concentration of the stressed material regions 320 in the grid 400 cause changes in the reflection profile (e.g., intensity vs. wavelength—tan(δ), phase vs. wavelength—cos(Ψ), where δ and Ψ are common scatterometry outputs known to those of ordinary skill in the art) measured by the scatterometry tool 240 as compared to the light scattering profile that would be present in grids 400 having reference characteristic values. Due to the variety of test structures 300, 350 provided. Various measurements may be taken to distinguish between the sources of variation. Through these comparisons, the pitch, depth, spacing, fill height, and/or stress dopant concentration of the stressed material regions 320 may be determined.

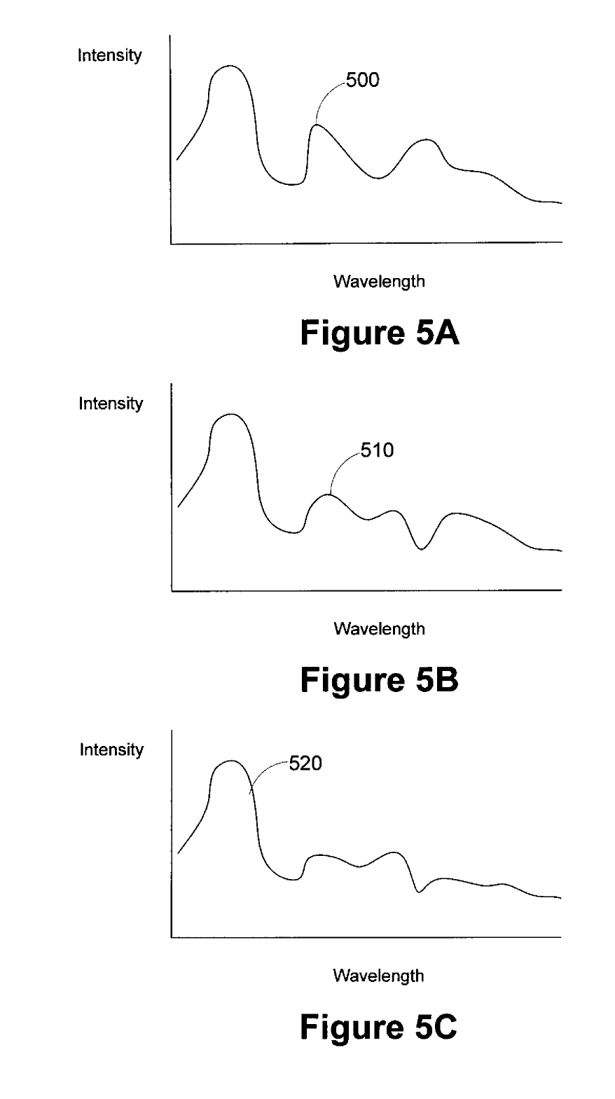

FIGS. 5A, 5B, and 5C illustrate exemplary reflection profiles 500, 510, 520 that may be included in a reference reflection profile library 248 (see FIGS. 2 and 4) used by the data processing unit 246 to characterize the features of the grid 400 (e.g., pitch, depth, spacing, fill height, stress dopant concentration, etc.) based on the reflection profiles measured by the scatterometry tool 240. The particular reflection profile expected for any structure depends on the specific geometry and materials of the test structure 300 and the parameters of the measurement technique employed by the scatterometry tool 240 (e.g., light bandwidth, angle of incidence, etc.). The profiles in the reference reflection profile library 248 are typically calculated theoretically by employing Maxwell's equations to model individual spectra based on the expected characteristics of the test structure 300, 350. Spectra are generated at a pre-determined resolution for many, if not all, profiles that may be expected, and the sum of all said spectra constitute the reference reflection profile library 248. Scatterometry libraries are commercially available from Timbre Technologies, Inc. The profiles in the reference reflection profile library 248 may also be generated empirically by measuring reflection profiles of sample wafers and subsequently characterizing the measured wafers by destructive or non-destructive examination techniques.

The reflection profile 500 of FIG. 5A represents an exemplary profile for a test structure 300 where the grid 400 has characteristics corresponding to design or target values. The reflection profile 510 of FIG. 5B represents an exemplary profile for a test structure 300 where the grid 400 exhibits a pitch slightly larger than a desired target value. The reflection profile 520 of FIG. 5C represents an exemplary profile for a test structure 300 where the grid 400 exhibits a decreased pitch. The reflection profiles of test structures 300 having grids 400 with different amounts pitch variation may be included in the reference reflection profile library 248. Similarly, reflection profiles may be included that correspond to variations in the depth of the stressed material regions 320, variations in the width of the stressed material regions 320, variations in the fill height, and variations in the concentration of stress dopant ions (e.g., germanium or carbon).

The data processing unit 246 receives a reflection profile measured by the detector 244 and compares it to the reference reflection profile library 248. Each reference profile has an associated stressed layer characteristic metric related to one or more characteristics of the grid 400 (e.g., X, Y, Z, F, or C). For example, the stressed layer characteristic metric may comprise actual width, depth, spacing, fill height, and/or concentration measurements. The data processing unit 246 determines the reference reflection profile having the closest match to the measured reflection profile. Techniques for matching the measured reflection profile to the closest reference reflection profile are well known to those of ordinary skill in the art, so they are not described in greater detail herein. For example, a least squares error technique may be employed.

In another embodiment, the controller 250 or other external controller (not shown) may be adapted to compare the measured reflection profile to the reference reflection profile library 248. In such a case, the scatterometry tool 240 would output the matching reference reflection profile, and the controller 250 may link that reference reflection profile to an associated stressed layer characteristic metric.

In still another embodiment, the measured reflection profile may be compared to a target reflection profile selected from the reference reflection profile library 248 for a test structure 300 having grid 400 exhibiting known and desired characteristics (e.g., the reflection profile 500 of FIG. 5A). For example, a target reflection profile may be calculated for a test structure 300 having grid 400 with ideal, or at least acceptable, characteristics using Maxwell's equations, and that target reflection profile may be stored in the reference reflection profile library 248. Thereafter, the measured reflection profile of a test structure 300 with stressed layer grids 400 having unknown characteristics is compared to the target reflection profile. Based upon this comparison, an approximation of the characteristics may be determined. That is, by comparing the measured reflection profile to the target reflection profile, the characteristics of the grid 400 may be approximated, such that further matching of the measured reflection profile with additional reference reflection profiles from the reference reflection profile library 248 is unwarranted. Using this technique, an initial determination may be made as to the characteristics of the stressed layer grid. Of course, this step may be performed in addition to the matching or correlating of a measured reflection profile to a reference reflection profile from the reference reflection profile library 248 as described above.

After receiving the stressed layer characteristic metric from the scatterometry tool 240, the controller 250 may take a variety of autonomous actions. In one embodiment of the present invention, the controller 250 is adapted to modify the operating recipe of the deposition tool 220 and/or the etch tool 230 based on the stressed layer characteristic metric to control operations on subsequently processed wafers. The controller 250 may adjust the recipe for subsequently processed wafers to control the characteristics of the grid 400 or the stress dopant concentration. Deposition parameters such as deposition time, chamber pressure, chamber temperature, reactant gas concentration, etc., or etch recipe parameters, such as the etch time, plasma chemical compositions, RF power, gas flow, chamber temperature, chamber pressure, end-point signal, etc., may be changed to correct variations in the width, spacing, depth, fill height, or stress dopant concentration of the stressed semiconductor material 170 in the actual device corresponding to the stressed material regions 320 in the test structures 300, 350.

The controller 250 may use a control model of the deposition tool 220 or the etch tool 230 for determining its operating recipe. For example, the controller 250 may use a control model relating the stressed layer characteristic metric to a particular operating recipe parameter in the controlled tool 220, 230 to control the process to correct for variation. This correction may also result in the correction of the process as it affects the other features formed on the device. The control model may be developed empirically using commonly known linear or non-linear techniques. The control model may be a relatively simple equation based model (e.g., linear, exponential, weighted average, etc.) or a more complex model, such as a neural network model, principal component analysis (PCA) model, or a projection to latent structures (PLS) model. The specific implementation of the model may vary depending on the modeling technique selected.

Grid characteristic models may be generated by the controller 250, or alternatively, they may be generated by a different processing resource (not shown) and stored on the controller 250 after being developed. The grid characteristic models may be developed using the tools 220, 230 or using different tools (not shown) having similar operating characteristics. For purposes of illustration, it is assumed that the grid characteristic models are generated and updated by the controller 250 or other processing resource based on the actual performance of the tools 220, 230 as measured by the scatterometry tool 240. The grid characteristic models may be trained based on historical data collected from numerous processing runs of the tools 220, 230.

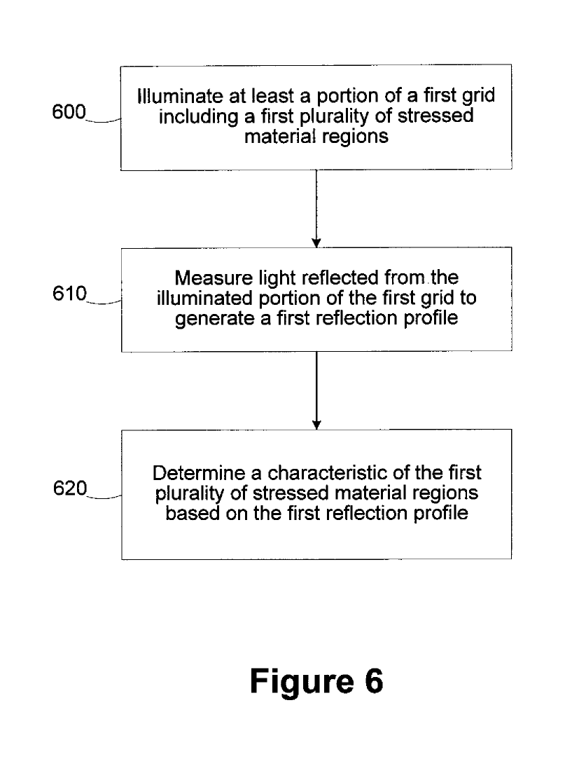

FIG. 6 is a simplified flow diagram of a method for determining characteristics of a stressed layer in accordance with another illustrative embodiment of the present invention. In method block 600, at least a portion of a first grid including a first plurality of stressed material regions is illuminated. In method block 610, light reflected from the illuminated portion of the first grid is measured to generate a first reflection profile. A characteristic of the first plurality of stressed material regions is determined based on the first reflection profile.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

We claim:

1. A method, comprising:
illuminating at least a portion of a first grid including a first plurality of stressed material regions formed at least partially in a semiconducting material;
measuring light reflected from the illuminated portion of the first grid to generate a first reflection profile; and
determining a characteristic of the first plurality of stressed material regions based on the first reflection profile.

2. The method of claim 1, wherein determining the characteristic of the first plurality of stressed material regions further comprises:
comparing the generated reflection profile to a library of reference reflection profiles, each reference reflection profile having an associated stressed layer characteristic metric;
selecting a reference reflection profile closest to the generated first reflection profile; and
determining the characteristic of the first plurality of stressed material regions based on the stressed layer characteristic metric associated with the selected reference reflection profile.

3. The method of claim 1, further comprising determining at least one parameter of an operating recipe of a etch tool adapted to etch a subsequent wafer based on the determined characteristic of the first plurality of stressed material regions.

4. The method of claim 1, further comprising determining at least one parameter of an operating recipe of a deposition tool adapted to process a subsequent wafer based on the determined characteristic of the first plurality of stressed material regions.

5. The method of claim 1, wherein generating the first reflection profile comprises generating the first reflection profile based on at least one of intensity and phase of the reflected light.

6. The method of claim 1, wherein determining the characteristic of the first plurality of stressed material regions further comprises:
comparing the generated first reflection profile to a target reflection profile; and
determining the characteristic of the first plurality of stressed material regions based on the comparison of the generated first reflection profile and the target reflection profile.

7. The method of claim 1, wherein determining the characteristic of the first plurality of stressed material regions further comprises determining at least one of a width dimension, a depth dimension, a spacing dimension, a fill height dimension, and a stress dopant concentration.

8. The method of claim 1, wherein the first plurality of stressed material regions are recessed with respect to a surface of a semiconductor layer.

9. The method of claim 8, wherein the semiconductor layer comprises silicon and the first plurality of stressed material regions comprises silicon and a stress dopant ion.

10. The method of claim 9, wherein the stress dopant ion comprises at least one of carbon or germanium.

11. The method of claim 1, further comprising:
patterning a mask layer to define a first masking grid on a semiconductor layer;
etching a first plurality of recesses in the semiconductor layer using the first masking grid;
forming the first plurality of stressed material regions in the first plurality of recesses to define the first grid; and
removing the mask layer.

12. The method of claim 11, further comprising:
patterning the mask layer to define a second masking grid on a semiconductor layer;
etching a second plurality of recesses in the semiconductor layer using the second masking grid;
forming a second plurality of stressed material regions in the second plurality of recesses to define a second grid;
illuminating at least a portion of the second grid;
measuring light reflected from the illuminated portion of the second grid to generate a second reflection profile; and
determining a characteristic of one of the first plurality of stressed material regions or the second plurality of stressed material regions based on the second reflection profile.

13. The method of claim 12, wherein the first and second grids differ in at least one of a width dimension of the first and second pluralities of stressed material regions, a spacing dimension between the first and second pluralities of stressed material regions, or a depth dimension of the first and second pluralities of stressed material regions.

14. A test structure, comprising:
a first plurality of stressed material regions recessed with respect to a surface of a semiconductor layer and defining a first grid; and
a first plurality of exposed portions of the semiconductor layer, members of the first plurality of exposed portions being disposed between members of the first plurality of stressed material regions.

15. The structure of claim 14, further comprising:
a second plurality of stressed material regions recessed with respect to the surface of the semiconductor layer and defining a second grid; and
a second plurality of exposed portions of the semiconductor layer, members of the second plurality of exposed portions being disposed between members of the second plurality of stressed material regions.

16. The structure of claim 15, wherein the first and second grids differ in at least one of a width dimension of the first and second pluralities of stressed material regions, a width dimension of the first and second pluralities of exposed portions of the semiconductor layer, and a depth dimension of the first and second pluralities of stressed material regions.

17. The structure of claim 15, wherein the semiconductor layer comprises silicon and the plurality of stressed material regions comprises silicon and a stress dopant ion.

18. The structure of claim 17, wherein the stress dopant ion comprises at least one of carbon or germanium.

19. A metrology tool adapted to receive a wafer having a test structure comprising a first grid including a first plurality of stressed material regions, comprising:
a light source adapted to illuminate at least a portion of the first grid;
a detector adapted to measure light reflected from the illuminated portion of the first grid to generate a first reflection profile; and
a data processing unit adapted to determine a characteristic of the first plurality of stressed material regions based on the first reflection profile.

20. A processing line, comprising:
a processing tool adapted to process wafers in accordance with an operating recipe;
a metrology tool adapted to receive a wafer having a test structure comprising a first grid including a first plurality of stressed material regions, the metrology tool comprising:
a light source adapted to illuminate at least a portion of the first grid;
a detector adapted to measure light reflected from the illuminated portion of the first grid to generate a first reflection profile; and
a data processing unit adapted to determine a characteristic of the first plurality of stressed material regions based on the first reflection profile; and
a controller adapted to determine at least one parameter of the operating recipe of the processing tool based on the determined characteristic of the first plurality of stressed material regions.

21. A metrology tool, comprising:
means for illuminating at least a portion of a first grid including a first plurality of stressed material regions;
means for measuring light reflected from the illuminated portion of the first grid to generate a first reflection profile; and
means for determining a characteristic of the first plurality of stressed material regions based on the first reflection profile.
